(19) United States
(12) Patent Application Publication
(10) Pub. No.: US 2010/0201698 A1
(43) Pub. Date: Aug. 12, 2010

(54) METHOD OF CONTROLLING TIMING SIGNALS, TIMING CONTROL APPARATUS FOR PERFORMING THE METHOD AND DISPLAY APPARATUS HAVING THE APPARATUS

(75) Inventor: Cheol-Ho LEE, Cheonan-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si, Gyeonggi-do (KR)

(21) Appl. No.: 12/501,642

(22) Filed: Jul. 13, 2009

(30) Foreign Application Priority Data
Feb. 10, 2009 (KR) 2009-0010683

(51) Int. Cl. G09G 5/10; H03K 3/289; G09G 5/00; G06F 13/00

(52) U.S. Cl. 345/536; 327/202; 345/213; 345/690

(57) ABSTRACT

A method of controlling timing signals includes; selectively providing both master control data and slave control data, which are included in control data, to a memory part based on a write enable signal provided form an external device, reading control data stored in the memory part in response to a reset signal provided from an external device, and controlling output timing of at least one power voltage based on the stored control data.

This application claims priority to Korean Patent Application No. 2009-10683, filed on Feb. 10, 2009, and all the benefits accruing therefrom under 35 U.S.C. §119, the contents of which in its entirety are herein incorporated by reference.

### BACKGROUND OF THE INVENTION

1. Field of the Invention

Exemplary embodiments of the present invention relate to a method of controlling timing signals, a timing control apparatus for performing the method, and a display apparatus having the timing control apparatus. More particularly, exemplary embodiments of the present invention relate to a method of controlling timing signals capable of enhancing the reliability of a display apparatus, a timing control apparatus for performing the method, and a display apparatus having the timing control apparatus.

2. Description of the Related Art

Generally, a display apparatus is an apparatus which displays an image by receiving an image signal from an information processing apparatus. Flat panel type display apparatuses, among the various types of display apparatuses, have various advantages, such as small size, light weight and high resolution, and thus the flat panel type display apparatuses are widely used.

Such flat panel type display apparatuses may be classified into liquid crystal display (“LCD”) apparatuses, plasma display panel (“PDP”) apparatuses, and other similar types of display apparatus.

Generally, LCD apparatuses, among the various types of flat panel type display apparatuses, have various advantages, such as thinner thickness, lighter weight, lower driving voltage requirements and lower power consumption, among various other advantageous features, compared to other types of display apparatuses. As a result, LCD apparatuses are widely employed in various electronic devices such as monitors, laptop computers, cellular phones, and other devices. An LCD device typically includes an LCD panel which displays an image using the light transmittance characteristics of liquid crystal molecules, and a driving part electrically connected to the LCD panel to control the LCD panel.

The driving part typically includes a timing control part, a data driving part, and a gate driving part. The timing control part outputs a data control signal and a gate control signal in response to an external control signal provided from an external device (not shown). The data driving part outputs a data signal to the LCD panel in response to the data control signal, and the gate driving part outputs a gate signal to the LCD panel in response to the gate control signal.

The driving part typically includes a memory part outputting control data that is an initial driving signal. The memory part may include an electrically erasable programmable read-only memory (“EEPROM”). Control data such as an extended display identification data (“EDID”) signal or other similar signal, is stored in advance in the EEPROM.

In order to realize a high resolution in a display apparatus, a frequency that is higher than a common frequency is used. For example, when the display apparatus is driven at 240 Hz, two control parts, e.g., timing controllers, and two memory parts are generally used.

However, situations arise wherein the two timing controllers may not read the control data stored in two corresponding memory parts accurately, and thus data conflicts may be generated. Thus, the reliability of the display apparatus may be decreased.

### BRIEF SUMMARY OF THE INVENTION

Exemplary embodiments of the present invention provide a method of controlling timing signal capable of enhancing the reliability of a display apparatus.

Exemplary embodiments of the present invention also provide a timing control apparatus for performing the above-mentioned method.

Exemplary embodiments of the present invention further also provide a display apparatus having the above-mentioned timing control apparatus.

According to one exemplary embodiment of the present invention, a method of controlling timing signals includes; selectively providing both master control data and slave control data, which are included in control data, to a memory part based on a write enable signal provided from an external device, reading control data stored in the memory part in response to a reset signal provided from an external device, and controlling output timing of at least one power voltage based on the stored control data.

In an exemplary embodiment of the present invention, controlling the output timing of the at least one power voltage may further include providing a master power voltage control signal and a slave power voltage control signal to a logic gate before providing a power voltage control signal to a power supply part. In such an exemplary embodiment, the output of the at least one power voltage may begin when the master power voltage control signal and the slave power voltage control signal are simultaneously at a high voltage level. Moreover, in one exemplary embodiment the master control data and the slave control data may be prevented from being independently provided to the memory part.

According to another exemplary embodiment of the present invention, a timing control apparatus includes; a power supply part which outputs at least one power voltage, a memory part which stores control data comprising master control data and slave control data, a timing control part which reads the control data from the memory part in response to a reset signal provided form an external device and which controls an output timing of the at least one power voltage, and a switching part which selectively provides the memory part with both the master control signal and the slave control signal, based on a write enable signal provided from an external source.

In an exemplary embodiment of the present invention, the switching part may include; a master switch which outputs the master control data in response to the write enable signal, and a slave switch which outputs the slave control data in response to the write enable signal.

In an exemplary embodiment of the present invention, the memory part may include; a master memory which stores the master control data in response to the write enable signal, and a slave memory which stores the slave control data in response to the write enable signal.

In an exemplary embodiment of the present invention, the timing control part may respectively read the master control data and the slave control data in response to the reset signal when the write enable signal is at a low voltage level, and the timing control part may provide the power supply part with a power voltage control signal in a high state when the master control data and the slave control data are normally read.

In an exemplary embodiment of the present invention, the timing control part may further include an AND gate which provides the power supply part with the power voltage control signal based on a master power voltage control signal and a slave power voltage control signal.

In an exemplary embodiment of the present invention, the timing controller may include a master timing controller and a slave controller. The master timing controller may read the master control data, and the slave timing controller may read the slave control data. In one exemplary embodiment, each of the master timing controller and the slave timing controller communicates with the memory part through one of an inter-integrated circuit and an inter-integrated circuit. In one exemplary embodiment, the memory part may be an electrically erasable programmable read-only memory (“EEPROM”).

In an exemplary embodiment of the present invention, the switching part may prevent the master control data and the slave control data from being independently provided to the memory part.

In an exemplary embodiment of the present invention, the at least one power voltage may include an analog driving voltage AVDD, a gate on voltage VON, a gate off voltage VOFF and a common voltage VCOM.

In an exemplary embodiment of the present invention, the memory part and the timing control part may be integrated with each other on a common single, unitary and indivisible substrate. Alternative exemplary embodiments include configurations wherein the memory part, the timing control part and the power supply part may be integrated with each other on a common single, unitary and indivisible substrate.

According to another exemplary embodiment of the present invention, a display apparatus includes; a timing control apparatus as described above, a gate driving part which receives the at least one power voltage from the power supply part and outputs a gate signal in response to a gate control signal provide from the timing control apparatus, a data driving part which receives the at least one power voltage from the power supply part and outputs a data signal in response to a data control signal provided from the timing control apparatus, and a display panel which displays an image based on the gate signal and the data signal.

In an exemplary embodiment of the present invention, the timing control part may read the master control data and the slave control data in response to the reset signal to output the gate control signal and the data control signal, respectively, when the write enable signal is at a low voltage level.

In an exemplary embodiment of the present invention, a driving frequency of the display panel may be about 240 Hz, and driving frequencies of the master timing controller and the slave timing controller may be 120 Hz, respectively.

In an exemplary embodiment of the present invention, the display apparatus may further include a gray scale voltage generating part which generates a gray scale voltage using an analog driving voltage as a reference voltage and outputs the gray scale voltage to the data driving part.

According to a method of controlling timing, a timing control apparatus for performing the method, and a display apparatus having the timing control apparatus, two timing controllers selectively access two memories using two switches, so that data conflicts may be prevented, and thus the reliability of a display apparatus may be enhanced.

### BRIEF DESCRIPTION OF THE DRAWINGS

The above and other aspects, features and advantages of exemplary embodiments of the present invention will become more apparent by describing in detailed exemplary embodiments thereof with reference to the accompanying drawings, in which:

FIG. 1 is a block diagram illustrating an exemplary embodiment of a display apparatus according to the present invention;

FIG. 2 is a block diagram illustrating an exemplary embodiment of the timing control apparatus of FIG. 1;

FIG. 3 is an equivalent circuit diagram illustrating an exemplary embodiment of the master switch of FIG. 2;

FIG. 4 is an equivalent circuit diagram illustrating an exemplary embodiment of the master memory of FIG. 2;

FIG. 5 is an equivalent circuit diagram illustrating an exemplary embodiment of the slave switch of FIG. 2;

FIG. 6 is an equivalent circuit diagram illustrating an exemplary embodiment of the slave memory of FIG. 2; and

FIG. 7 is a flowchart showing an exemplary embodiment of a control method of the exemplary embodiment of a timing control apparatus of FIG. 1.

### DETAILED DESCRIPTION OF THE INVENTION

The invention now will be described more fully hereinafter with reference to the accompanying drawings, in which various exemplary embodiments are shown. This invention may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-sectional illustrations that are schematic illustrations of idealized exemplary embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In another example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

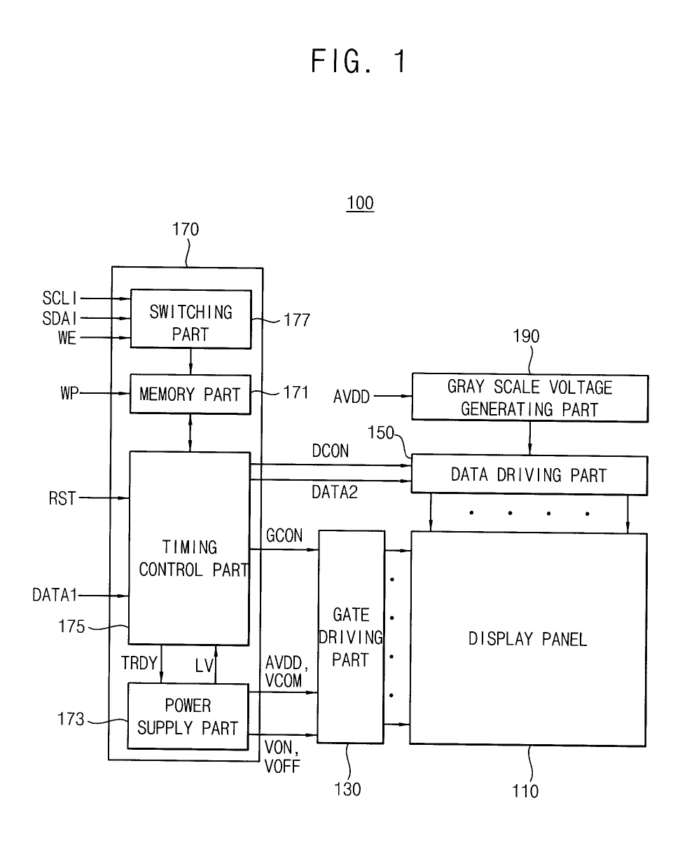

FIG. 1 is a block diagram illustrating an exemplary embodiment of a display apparatus 100 according to the present invention.

Referring to FIG. 1, a display apparatus 100 includes a display panel 110, a gate driving part 130, a data driving part 150, a timing control apparatus 170 and a gray scale voltage generating part 190.

The display panel 110 displays an image based on a gate signal output from the gate driving part 130 and a data signal output from the data driving part 150.

The display panel 110 may be a liquid crystal display (“LCD”) panel which includes two substrates and a liquid crystal layer interposed therebetween to display an image. The LCD panel includes a plurality of pixels for displaying an image. In the present exemplary embodiment, each of the pixels includes a switching element connected to a gate line and a data line, a liquid crystal capacitor electrically connected to the switching element and a storage capacitor electrically connected to the switching element. Alternative exemplary embodiments include configurations wherein the storage capacitor may be omitted. Alternative exemplary embodiments may include configurations wherein the display panel 110 includes other types of displays, such as plasma displays and organic light emitting diode (“OLED”) displays. In the exemplary embodiment wherein the display apparatus 100 includes an LCD in the display panel 110, the display apparatus 100 may further include a backlight assembly (not shown) disposed below the LCD panel to provide the LCD panel with light.

The gate driving part 130 outputs a gate signal to the display panel 100 in response to a power voltage and a gate control signal GCON that are provided from the timing control apparatus 170. Here, the power voltage may be an analog driving voltage AVDD, a common voltage VCOM, a gate on voltage VON, a gate off voltage VOFF, or other similar voltages. Exemplary embodiments of the gate driving part 130 may include at least one gate driving unit.

The data driving part 150 outputs a data signal to the display panel 110 in accordance with a data control signal DCON provided from the timing control apparatus 170. Exemplary embodiments of the data driving part 150 may further include at least one data driving unit (not shown).

The timing control apparatus 170 receives a reset signal RST, a serial clock signal SCLI, a serial data signal SDAI, a write enable signal WE, a write protection signal WP and a first data signal DATA1 for displaying an image from an external device (not shown), and outputs a second data signal DATA2, which is a timing controlled version of the first data signal DATA1, the data control signal DCON, the gate control signal GCON and the power voltage.

The timing control apparatus 170 may further receive synchronizing signals such as a vertical synchronizing signal Vsync, a horizontal synchronizing signal Hsync, a data enable signal DE, and various other synchronizing signals. The vertical synchronizing signal Vsync represents a time required for displaying one frame. The horizontal synchronizing signal Hsync represents a time required for displaying one line of the frame. The data enable signal DE represents a time required for supplying the pixel with data, e.g., in the exemplary embodiment wherein the display panel 110 is an LCD the data enable signal DE may represent a time sufficient for charging the liquid crystal capacitor of an individual pixel.

Exemplary embodiments of the data control signal DCON may include a clock signal, a horizontal start signal STH, and various other similar signals. The gate control signal GCON may include a vertical start signal STV and various other similar signals.

In the present exemplary embodiment, the timing control apparatus 170 includes a memory part 171, a power supply part 173, a timing control part 175 and a switching part 177. In one exemplary embodiment, the memory part 171, the timing control part 175 and the switching part 177 may be individually mounted on separate substrates. Alternative exemplary embodiments include configurations wherein the memory part 171, the timing control part 175 and the switching part 177 may be jointly integrated onto a single substrate.

The memory part 171 receives the write protection signal WP provided from an external device to provide the timing control part 175 with control data. The control data may be control data for controlling image display on the display panel 1 10.

The power supply part 173 provides the timing control part 175 with a logic driving voltage LV for driving a logic circuit disposed therein, and outputs the power voltage to the gate driving part 130. For example, in one exemplary embodiment, the power voltage may include an analog driving voltage AVDD, a common voltage VCOM, a gate on voltage VON, a gate off voltage VOFF, and other similar voltages.

The timing control part 175 receives the control data from the memory part 171, and receives the logic driving voltage LV from the power supply part 173. The timing control part 175 receives the reset signal RST and the first data signal DATA1 from an external device (not shown).

The timing control part 175 provides the gate driving part 130 with the gate control signal GCON which controls the gate driving part 130, and provides the data driving part 150 with the data timing signal DCON which controls the data driving part 150 and the second data signal DATA2. Moreover, the timing control part 175 outputs a power voltage control signal TRDY which controls output timing of the power voltage.

The switching part 177 receives the serial clock signal SCLI, the serial data signal SDAI and the write enable signal WE from an external device (not shown). The switching part 177 provides the memory part 171 with the serial clock signal SCLI and the serial data signal SDAI in response to the write enable signal WE. Here, the serial data signal SDAI includes the control data sent from the memory part 171 to the timing control part 175, and the serial clock signal SCLI is a reference clock signal for controlling a timing of the serial data signal SDAI.

The gray scale voltage generating part 190 generates a gray scale voltage by using the analog driving voltage AVDD as a reference voltage, and then provides the data driving part 150 with the gray scale voltage. In one exemplary embodiment, the gray scale voltage generating part 190 may generate a plurality of gray scale voltages.

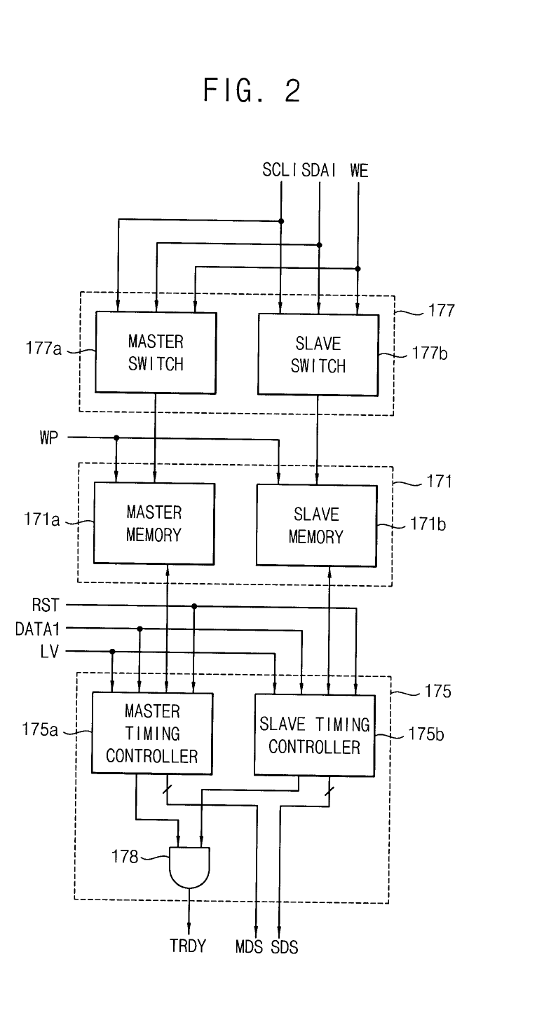

FIG. 2 is a block diagram illustrating an exemplary embodiment of the timing control apparatus of FIG. 1.

Referring to FIGS. 1 and 2, the memory part 171 stores the control data. In one exemplary embodiment, the control data may be control data for controlling image display on the display panel 110. For example, in one exemplary embodiment the data for controlling image display may include a timing signal for a clock signal CLK, a horizontal start signal STH, and a vertical start signal STV, a gamma reference voltage, and other similar signals.

The memory part 171 provides the timing control part 175 with the control data. In one exemplary embodiment, the memory part 171 may be electrically erasable programmable read-only memory (“EEPROM”) which can be programmed and erased electrically using field emission. In one exemplary embodiment, the EEPROM may be connected to an external memory writer (not shown) to perform a writing operation, and then perform a reading operation during the display apparatus 100 is operated to display an image . . . .

In the present exemplary embodiment, the memory part 171 includes a master memory 171a and a slave memory 171b.

In this exemplary embodiment, pixels of the display panel 110 display an image in accordance with master control data stored in the master memory 171a and slave control data stored in the slave memory 171b as will be discussed in detail below.

In the present exemplary embodiment, a master area that is a first area of pixels in the display panel 110, which displays an image using the control data stored in the master memory 171a, and a slave area that is a second area of pixels in the display panel 110, which displays an image using the control data stored in the slave memory 171b, define a whole pixel area of the display panel 110.

In one exemplary embodiment, in response to the write protection signal WP, the master and slave memories 171a and 171b respectively read the control data corresponding to the master area or the control data corresponding to the slave area from the switching part 177, and store the control data therein. In another exemplary embodiment, in response to the write protection signal WP, the master and slave memories 171a and 171b respectively read the control data corresponding to the master area or the control data corresponding to the slave area from the switching part 177, and provide the timing control part 175 with the control data.

In one exemplary embodiment, the write protection signal WP is a signal which has a substantially inverted phase with respect to the write enable signal WE.

That is, when a user stores information corresponding to the control data, the memory part 171 stores the control data in response to the write enable signal WE of a high level. The memory part 171 provides the control data to the timing control part 175 in response to the write protection signal WP of a high level when the display apparatus 100 start to operate to display an image.

In one exemplary embodiment, the power supply part 173 may be a DC-DC converter. The power supply part 173 outputs the power voltage. For example, in one exemplary embodiment the power voltage may include the analog driving voltage AVDD, the common voltage VCOM, the gate on voltage VON, the gate off voltage VOFF, a logic driving voltage LV, and other similar voltages.

The analog driving voltage AVDD and the common voltage VCOM represent analog voltage sources which provide a gray scale voltage or a common voltage to the display panel 110.

The gate on voltage VON and the gate off voltage VOFF represent a digital voltage source that is applied to a logic circuit. That is, the gate signals for turning on or turning off a switching element (not shown) connected to the gate line of the display panel 110 are generated based on the gate on/off voltages VON/VOFF. In one exemplary embodiment, the switching element may include a thin-film transistor (“TFT”).

The logic driving voltage LV is a voltage for operating logics of the timing control part 175. Not shown in FIGS. 1 and 2, the logic driving voltage LV may operate the gate driving part 130, the data driving part 150, the memory part 171 and the switching part 177 of the timing control apparatus 170, and logic circuits of the gray scale voltage generating part 190.

In the present exemplary embodiment, the timing control part 175 includes a master timing controller 175a and a slave timing controller 175b.

The master controller 175a and the slave timing controller 175b independently read the control data from the master memory 171a and the slave memory 171b, respectively.

In one exemplary embodiment, each of driving frequencies of the master timing controller 175a and the slave timing controller 175b may be about 120 Hz. Thus, the display apparatus 100 may be driven at about 240 Hz by the timing control part 175.

Each of the master timing controller 175a and the slave timing controller 175b receives the logic driving voltage LV, the reset signal RST and the first data signal DATA1. Each of the master timing controller 175a and the slave timing controller 175b outputs a master driving signal MDS, a master power voltage control signal MTRDY, a slave driving signal SDS and a slave power voltage control signal STRDY.

Here, the master driving signal MDS and the slave driving signal SDS are defined as a driving signal (not shown). The driving signal is a signal which is generated by the timing control part 175 based on the control data.

The driving signal may be provided to the gate driving part 130 and the data driving part 150. For example, in one exemplary embodiment the driving signal may include the second data signal DATA2, the data control signal DCON and the gate control signal GCON. In the present exemplary embodiment, the master driving signal MDS and the slave driving signal SDS may both respectively include the gate control signal GCON; however, alternative exemplary embodiments of the display apparatus 100 may be designed to use the gate control signal GCON included only in the master driving signal MDS.

Moreover, the data control signal DCON may further include a clock signal, a horizontal start signal STH, and other similar signals.

When the reset signal RST is applied to the timing control part 175, the timing control part 175 reads the control data stored in the memory part 171 to set as new data. For example, in one exemplary embodiment the timing control part 175 reads the control data that are stored in the memory part 171 to convert the stored control data into control signals and power voltages capable of being used in the gate driving part 140 and the data driving part 150, and then outputs the control signals and power voltages to the gate driving part 130 and the data driving part 150.

The switching part 177 includes a master switch 177a and a slave switch 177b. Each of the master switch 177a and the slave switch 177b receives the serial clock signal SCLI, the serial data signal SDAI and the write enable signal WE.

In the present exemplary embodiment, the serial data signal SDAI is a signal including bit information for the control data to be delivered, and the serial clock signal SCLI is a signal including a synchronizing clock signal for delivering the control data. The serial data signal SDAI is provided to the timing control part 175 to control the displaying of the display panel 110.

The master switch 177a receives the serial clock signal SCLI in response to the write enable signal WE. The slave switch 177b also receives the serial clock signal SCLI in response to the write enable signal WE.

In the present exemplary embodiment, a master serial clock signal MSCL of the serial clock signal SCLI corresponding to the master memory 171a may be transmitted to the master memory 171a based on an address of the master memory 171a. In addition, a slave serial clock signal SSCL of the serial clock signal SCLI corresponding to the slave memory 171b may be transmitted to the slave memory 171b based on an address of the slave memory 171b.

Since the display apparatus 100 only performs a reading function after a user stores information corresponding to the control data, the write enable signal WE is at a low level, and thus the write protection signal WP is at a high level.

When the write protection signal WP is at a high level, the timing control part 175 may use the control data written to the memory part 171.

For example, in an exemplary embodiment in which the write protection signal WP is a high level, when the reset signal RST is applied to the timing control part 175, the timing control part 175 may use the control data by setting the control data to be substantially the same as that written to the memory part 171.

Here, since the control data are selectively written to the master memory 171a and the slave memory 171b by the switching part 177, each of the master timing controller 175a and the slave timing controller 175b may output the master driving signal MDS, the master power voltage control signal MTRDY, the slave driving signal SDS and the slave power voltage control signal STRDY.

The timing control apparatus 170 may further include a power voltage control signal generating part 178 including an AND gate. Thus, when the master power voltage control signal MTRDY and the slave power voltage control signal STRDY simultaneously are at a high level, the power control signal generating part 178 outputs a power control signal TRDY of a high level.

The power voltage control signal TRDY of the high level represents that the control data corresponding to the master area and the slave area are normally read from the master memory 171a and the slave memory 171b, respectively. Thus, the power voltage control signal TRDY of the high level activates the power supply part 173 to normally operate the gate driving part 130, the data driving part 150 and the gray scale voltage generating part 190.

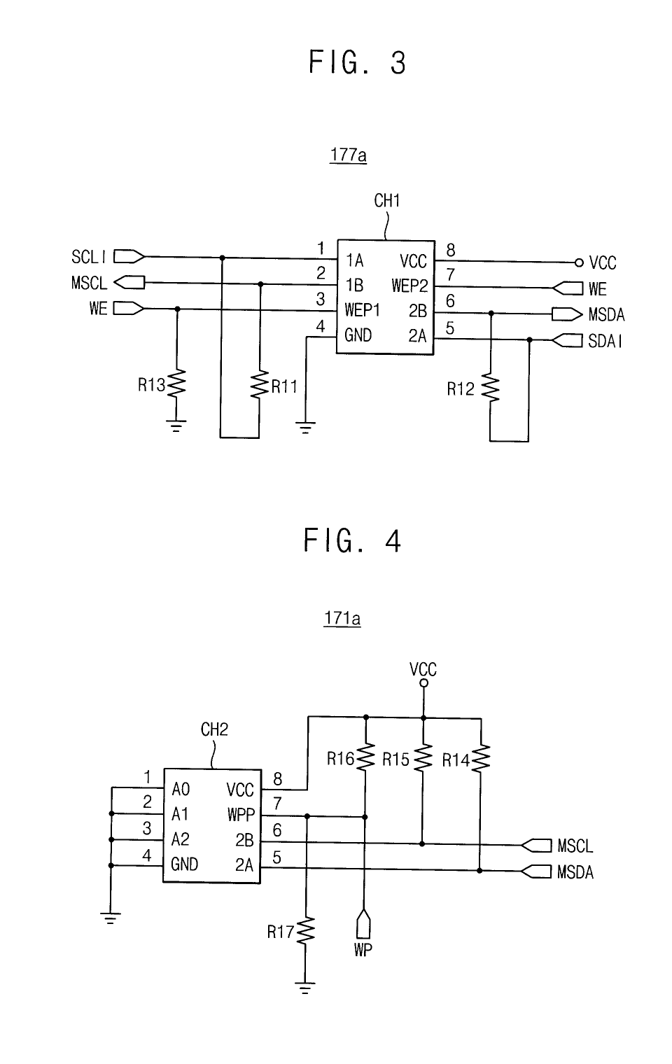

FIG. 3 is an equivalent circuit diagram illustrating an exemplary embodiment of the master switch of FIG. 2. FIG. 4 is an equivalent circuit diagram illustrating an exemplary embodiment of the master memory of FIG. 2.

Referring to FIGS. 2 to 4, the master switch 177a and the master memory 171a bidirectionally communicate with each other using two signals, for example, in one exemplary embodiment the master memory 171a and the master switch 177a utilize an inter-integrated circuit (also referred to as inter-IC or I²C) serial bus communication method, and the master memory 171a and the master timing controller 175a bidirectionally communicate with each other using two signals, for example, in one exemplary embodiment the master timing controller 175a and the master memory 171 communicate through the I²C serial bus communication method. Although not shown in FIGS. 2 to 4, the serial data signal SDAI may include a serial data SDA line and the serial clock signal SCL1 may include a serial clock SCL line.

The master switch 177a includes a first chip CH1 that is a switching chip. In the present exemplary embodiment, the first chip CH1 includes eight terminals.

A first terminal 1A receives the serial clock signal SCLI, respectively, and a second terminal 1B outputs the master serial clock signal MSCL. A third terminal WEP1 receives the write enable signal WE. The master serial clock signal MSCL may be output from the second terminal 1B in response to the write enable signal WE. A fourth terminal GND is a ground terminal of the master switch 177a.

A fifth terminal 2A and a sixth terminal 2B receive the serial data signal SDAI and output the master serial data MSDA, respectively. A seventh terminal WEP2 is a terminal receiving the write enable signal WE. The master serial data signal MSDA may be output from the sixth terminal 2B in response to the write enable signal WE received at the seventh terminal WEP2. An eighth terminal VCC is a power terminal of the master switch 177a to receive a power voltage VCC from an external device (not shown).

Here, the serial clock signal SCLI that is a synchronizing clock for delivering the control data through the serial clock SCL line is delivered to the first chip CH1, and the serial data signal SDAI, which is data including bit information for the control data to be delivered through the serial data SDA line, is delivered to the first chip CH1.

Moreover, exemplary embodiments include configurations wherein a first resistor R11 may be disposed between the first terminal 1A and the second terminal 1B, and a second resistor R12 may be disposed between the fifth terminal 2A and the sixth terminal 2B. In the present exemplary embodiment, the first and second resistors R11 and R12 have a high resistance. Thus, an electrical connection between the first terminal 1A and the second terminal 1B may be opened through the first resistor R11, and an electrical connection between the fifth terminal 2A and the sixth terminal 2B may be opened through the second resistor R12.

A first terminal of the third resistor R13 may be connected to the third terminal WEP1. A second terminal of the third resistor R13 maybe grounded.

As discussed above, in one exemplary embodiment the master memory 171a may be an EEPROM. The master memory 171a includes a second chip CH2 that is a memory chip. In the present exemplary embodiment, the second chip includes eight terminals.

A first terminal A0, a second terminal A1 and a third terminal A2 represent an address of the master memory 171a. In the present exemplary embodiment, the address of the master memory 171a maybe “000.” Thus, the first terminal A0, the second terminal A1 and the third terminal A2 are electrically connected to a fourth terminal GND that is a ground terminal.

A fifth terminal 2A and a sixth terminal 2B are terminals that the master serial clock signal MSCL and the master serial data signal MSDA that are outputted from the master switch 177a, respectively, are applied thereto. A seventh terminal WPP is a terminal to which the write protection signal WP is applied, and an eighth terminal VCC is a power terminal which receives a power voltage VCC from an external device (not shown).

Here, a fourth resistor R14, a fifth resistor R15 and a sixth resistor R16 may be connected to the fifth terminal 2A, the sixth terminal 2B and the seventh terminal WPP, respectively, to receive the power voltage VCC.

Moreover, a first terminal of the seventh resistor R17 may be connected to the seventh terminal WPP, and a second terminal of the seventh resistor R17 may be connected to a ground terminal. In the present exemplary embodiment, the seventh resistor R17 may have a high resistance. Thus, the seventh terminal WPP may be opened to the ground through the seventh resistor R17.

Thus, when an enable signal WE of a high voltage level is applied to the master switch 177a, the master switch 177a passes the master serial clock signal MSCL and the master serial data signal MSDA to be provided to the master memory 171a.

Here, since an address of the master memory 171a represents ‘000’, that is, since the first terminal A0, the second terminal A1 and the third terminal A2 are grounded, the master serial data signal MSDA based on the master clock signal MSCL may be written to the master memory 171a.

When the write enable signal WE is at a low voltage level so that the write protection signal WP is at a high voltage level, the master memory 171b may provide the master timing controller 175a with the master serial data signal MSDA.

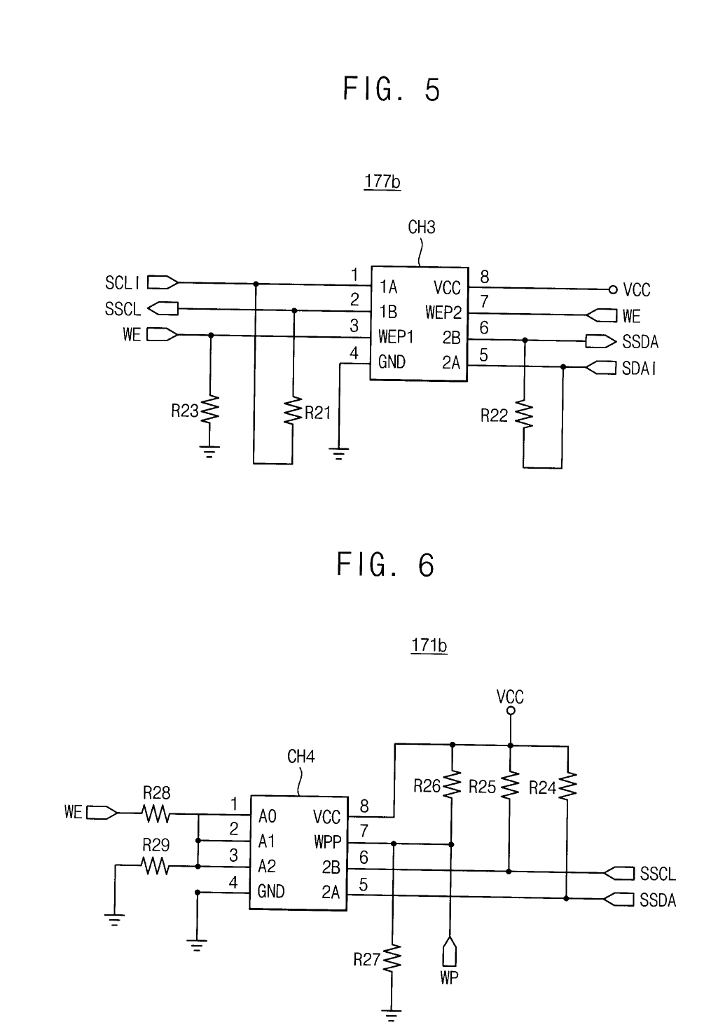

FIG. 5 is an equivalent circuit diagram illustrating an exemplary embodiment of the slave switch 177b of FIG. 2. FIG. 6 is an equivalent circuit diagram illustrating the slave memory 171b of FIG. 2.

Referring to FIGS. 2 to 6, in the present exemplary embodiment the slave switch 177b and the slave memory 171b bidirectionally communicate with each other using two signals, for example, in one exemplary embodiment through an I²C serial bus communication method, and the slave memory 171b and slave timing controller 175b bidirectionally communicate with each other using two signals, for example, in one exemplary embodiment through the I²C serial bus communication method. Although not shown in FIG. 2, the signal lines may include a serial SDA data line and a serial clock SCL line.

The slave switch 177b includes a third chip CH3 that is a switching chip. In the present exemplary embodiment, the third chip CH3 includes eight terminals.

A first terminal 1A and a second terminal 1B receive the serial clock signal SCLI and output the slave serial clock signal SSCL, respectively. A third terminal WEP1 is a terminal receiving the write enable signal WE. The slave serial clock signal SSCL may be output from the second terminal 1B in response to the write enable signal WE. A fourth terminal GND is a ground terminal of the slave switch 177b.

A fifth terminal 2A and a sixth terminal 2B receive the serial data signal SDAI and output the master serial data MSDA, respectively. A seventh terminal WEP2 is a terminal receiving the write enable signal WE. The slave serial data signal SSDA may be output from the sixth terminal 2B in response to the write enable signal WE. An eighth terminal VCC is a power terminal of the slave switch 177b to receive a power voltage VCC from an external device (not shown).

Here, a first resistor R21 may be disposed between the first terminal 1A and the second terminal 1B, and a second resistor R22 may be disposed between the fifth terminal 2A and the sixth terminal 2B. In the present exemplary embodiment the first and second resistors R21 and R22 have a high resistance. Thus, an electrical connection between the first terminal 1A and the second terminal 1B may be opened through the first resistor R21, and an electrical connection between the fifth terminal 2A and the sixth terminal 2B may be opened through the second resistor R22.

A first terminal of the third resistor R13 may be connected to the third terminal WEP1. A second terminal of the third resistor R13 maybe grounded.

As discussed above, exemplary embodiments include configurations wherein the slave memory 171b maybe EEPROM. The slave memory 171b includes a fourth chip CH4 that is a memory chip. In the present exemplary embodiment, the fourth chip CH4 includes eight terminals.

A first terminal A0, a second terminal A1 and a third terminal A2 represent an address of the slave memory 171b. In the present exemplary embodiment, the address of the slave memory 171b maybe “111.”

A fourth terminal GND is a ground terminal. A fifth terminal 2A and a sixth terminal 2B are terminals that the slave serial data signal SSDA and slave serial clock signal SSCL that are output from the slave switch 177b, respectively, are applied thereto. A seventh terminal WPP is a terminal to which the write protection signal WP is applied, and an eighth terminal VCC receives a power voltage VCC from an external device (not shown).

Here, a fourth resistor R24, a fifth resistor R25 and a sixth resistor R26 may be connected to the fifth terminal SCL, the sixth terminal SDA and the seventh terminal WPP, respectively, to receive the power voltage VCC.

Moreover, a first terminal of the seventh resistor R27 may be connected to the seventh terminal WPP, and a second terminal of the seventh resistor R27 may be connected to a ground terminal. In the present exemplary embodiment, the seventh resistor R27 may have a high resistance. Thus, the seventh terminal WPP may be connected to the ground terminal through the seventh resistor R27.

Therefore, when the write enable signal WE of a high voltage level is applied to the slave switch 177b, the slave switch 177b pass the slave serial clock signal SSCL and the slave serial data signal SSDA to provide the slave memory 171b with the slave serial clock signal SSCL and the slave serial data signal SSDA.

Here, since an address of the slave memory 171b represents ‘111’, that is, since the slave memory 171b is selected when a high voltage level signal is applied to a first terminal A0, the second terminal A1 and the third terminal A2, the slave serial data signal SSDA based on the slave serial clock signal SSCL is written to the slave memory 171b.

When the write enable signal WE is a low voltage level so that the write protection signal WP is at a high voltage level, the slave memory 171a may provide the slave timing controller 175b with the slave serial data signal SSDA.

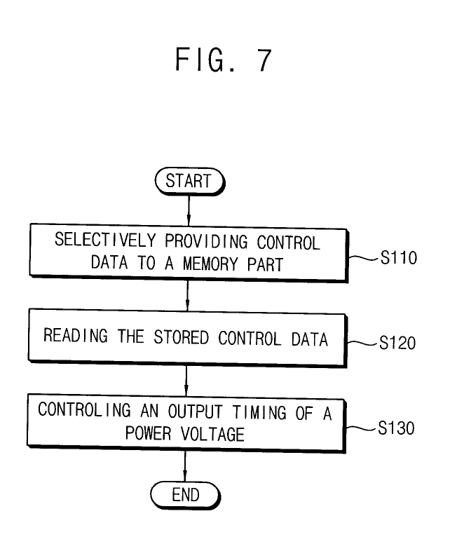

FIG. 7 is a flowchart showing a control method of the timing control apparatus of FIG. 1.

Referring to FIGS. 1, 2 and 7, master control data and slave control data that are included in new control data, e.g., the serial data signal SDAI synchronized by the serial clock signal SCLI is prevented from being provided to the memory part 171 based on the write enable signal WE provided from an external device (not shown) (step S110). Specifically, the new control data are not written to the memory part 171 when the write enable signal WE is in a low voltage state.

Then, the timing control part 175 reads the stored control data in response to the reset signal RST (step S120).

Then, the timing control part 175 controls output timing of power voltages outputted from the power supply part 173 based on the stored control data (step S130). Here, the timing control part 175 provides the power supply part 173 with the power control signal TRDY, so that the controlling of the timing control part 175 may be performed.

According to the present exemplary embodiment, the master switch 177a and the slave switch 177b may output the master serial clock signal MSCL and the slave serial clock signal SSCL, respectively, in response to the write enable signal WE.

Similarly, the master switch 177a and the slave switch 177b may output the master serial data MSDA and the slave serial data signal SSDA, respectively, in response to the write enable signal WE.

Moreover, the master memory 171a and the slave memory 171b may selectively store one of the master serial data signal MSDA synchronized by the master serial clock signal MSCL and the slave serial clock signal SSDA synchronized by the slave serial clock signal SSCL in accordance with addresses of the master memory 171a and the slave memory 171b. Thus, the timing control apparatus 170 may independently store the control data corresponding to the master area to the master memory 171a and the control data corresponding to the slave area to the slave memory 171b in response to the write enable signal WE.

Furthermore, the timing control apparatus 170 only uses the control data stored in response to the write protection signal WP, and an operation of the master switch 177a and an operation of the slave switch 177b may be blocked. Thus, when the master timing controller 175a and the slave timing controller 175b respectively read the control data from the master memory 171a and the slave memory 171b, the master timing controller 175a and the slave timing controller 175b independently access the master memory 171a and the slave memory 171b without data conflicts so that the reliability of the display apparatus 100 may be enhanced.

As described above, according to exemplary embodiments of the present invention, two timing controllers selectively access two memories using two switches, so that data conflicts may be prevented, and thus the reliability of a display apparatus may be enhanced.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A method of controlling timing signals, the method comprising:
selectively providing both master control data and slave control data, which are including control data, to a memory part based on a write enable signal provided from an external device;
reading control data stored in the memory part in response to a reset signal provided from an external device; and
controlling output timing of at least one power voltage based on the stored control data.

2. The method of claim 1, wherein controlling the output timing of the at least one power voltage further comprises providing a master power voltage control signal and a slave power voltage control signal to a logic gate before providing a power voltage control signal to a power supply part.

3. The method of claim 2, wherein an output of the at least one power voltage begins when the master power voltage control signal and the slave power voltage control signal are simultaneously at a high voltage level.

4. The method of claim 1, wherein the master control data and the slave control data are prevented from being independently provided to the memory part.

5. A timing control apparatus comprising:
a power supply part which outputs at least one power voltage;
a memory part which stores control data comprising master control data and slave control data;
a timing control part which reads the control data from the memory part in response to a reset signal provided from an external device and which controls an output timing of the at least one power voltage; and
a switching part which selectively provides the memory part with both the master control signal and the slave control signal, based on a write enable signal provided from an external device.

6. The timing control apparatus of claim 5, wherein the switching part comprises:
a master switch which outputs the master control data in response to the write enable signal; and
a slave switch which outputs the slave control data in response to the write enable signal.

7. The timing control apparatus of claim 6, wherein the memory part comprises:
a master memory which stores the master control data in response to the write enable signal; and
a slave memory which stores the slave control data in response to the write enable signal.

8. The timing control apparatus of claim 7, wherein the timing control part respectively reads the master control data and the slave control data in response to the reset signal when the write enable signal is at a low voltage level, and
the timing control part provides the power supply part with a power voltage control signal in a high state when the master control data and the slave control data are normally read.

9. The timing control apparatus of claim 8, wherein the timing control part further comprises an AND gate which provides the power supply part with the power voltage control signal based on a master power voltage control signal and a slave power voltage control signal.

10. The timing control apparatus of claim 5, wherein the timing controller comprises a master timing controller and a slave timing controller, the master timing controller reads the master control data, and the slave timing controller reads the slave control data.

11. The timing control apparatus of claim 5, wherein the memory part is an electrically erasable programmable read-only memory.

12. The timing control apparatus of claim 5, wherein the switching part prevents the master control data and the slave control data from being independently provided to the memory part.

13. The timing control apparatus of claim 5, wherein the at least one power voltage comprises an analog driving voltage, a gate on voltage, a gate off voltage and a common voltage.

14. The timing control apparatus of claim 5, wherein the memory part and the timing control part are integrated with each other on a common single, unitary and indivisible substrate.

15. The timing control apparatus of claim 5, wherein the memory part, the timing control part and the power supply part are integrated with each other on a common single, unitary and indivisible substrate.

16. A display apparatus comprising:
a timing control apparatus comprising:
a power supply part which outputs at least one power voltage;
a memory part which stores control data comprising master control data and slave control data;
a timing control part which reads the control data from the memory part in response to a reset signal provided from an external device and controls output timing of the at least one power voltage; and
a switching part which selectively provides the memory part with the master control data and the slave control data based on a write enable signal provided from an external device,
a gate driving part which receives the at least one power voltage from the power supply part and outputs a gate signal in response to a gate control signal provided from the timing control apparatus;
a data driving part which receives the at least one power voltage from the power supply part and outputs a data signal in response to a data control signal provided from the timing control apparatus; and
a display panel which displays an image based on the gate signal and the data signal.

17. The display apparatus of claim 16, wherein the timing control part reads the master control data and the slave control data in response to the reset signal to output the gate control signal and the data control signal, respectively, when the write enable signal is at a low voltage level.

18. The display apparatus of claim 16, wherein a driving frequency of the display panel is about 240 Hz.

19. The display apparatus of claim 16, wherein,
the memory part comprises:
a master memory which stores the master control data; and
a slave memory which stores the slave control data,
the timing control apparatus comprises:
a master timing controller which reads the master control data from the master memory; and
a slave timing controller which reads the slave control data from the slave memory, and
a driving frequency of the master timing controller and the slave timing controller is about 120 Hz, respectively.

20. The display apparatus of claim 16, further comprising:
a gray scale voltage generating part which generates a gray scale voltage using an analog driving voltage as a reference voltage and outputs the gray scale voltage to the data driving part.
